(19) United States
(12) Patent Application Publication
(10) Pub. No.: US 2026/0052656 A1
(43) Pub. Date: Feb. 19, 2026

(54) METHOD AND APPARATUS FOR COOLING SYSTEM

(71) Applicant: NextAire, LLC, Las Vegas, NV (US)

(72) Inventors: Tommis Young, Las Vegas, NV (US); Yue Zha, Changzhou (CN)

(73) Assignee: NextAire, LLC, Las Vegas, NV (US)

(21) Appl. No.: 18/809,317

(22) Filed: Aug. 19, 2024

(51) Int. Cl. H05K 7/20

(52) U.S. Cl. CPC H05K 7/20672; H05K 7/20309; H05K 7/20318; H05K 7/20327; H05K 7/20609

(57) ABSTRACT

The present system provides an improved architecture for cooling server cabinets as well as adapting operations based on dynamic energy costs. The system utilizes a small oil-free compressor, which is distributed on the top of the cabinet, reducing the distance from the evaporator outlet to the compressor suction port, and combines phase change energy storage material and free cooling control technology to achieve further energy-saving effects. The technical scheme adopted by the invention to solve the technical problem is an oil-free direct-expansion cooled communication cabinet, characterized in that it is comprised of an oil-free compressor, with at least one condenser and one evaporator, a throttling device, a gas-liquid separation device, and a communication cabinet. The system stores cold capacity when energy costs are low and releases stored cold capacity when energy costs are high.

### BACKGROUND OF THE SYSTEM

Cooling high power computing and edge data centers is a critical challenge due to several key issues:
1. Energy Consumption: Cooling systems in data centers can consume a significant amount of energy, sometimes nearly as much as the IT equipment itself. This not only increases operational costs but also contributes to environmental concerns.
2. Heat Density: Modern data centers house densely packed servers that generate substantial heat. Managing this heat efficiently and evenly across the facility is crucial to prevent equipment overheating and potential failures.
3. Airflow Management: Proper airflow is essential for cooling effectiveness. Issues such as hot spots (areas with higher temperatures), airflow obstructions, and inadequate ventilation can compromise cooling efficiency and overall data center performance.
4. Scale and Growth: As data centers expand to accommodate increasing demand for cloud services and data storage, the cooling requirements grow exponentially. This scalability challenge requires innovative solutions to maintain efficiency at larger scales.
5. Environmental Impact: The energy-intensive cooling systems contribute to carbon emissions and environmental impact. Finding sustainable cooling solutions, such as using renewable energy sources or improving energy efficiency, is crucial for reducing this footprint.
6. Cost: Cooling represents a significant portion of a data center's operational expenses. Balancing efficient cooling solutions with cost-effectiveness is a constant concern for data center operators.
7. Technological Advances: New technologies in server design and cooling systems continually evolve, presenting both opportunities and challenges. Adopting these advancements while ensuring compatibility and efficiency requires careful planning and investment.

Addressing these challenges involves a combination of advanced cooling technologies, efficient facility design, strategic airflow management, and a commitment to sustainability. As data centers continue to grow in importance, managing their cooling needs effectively remains a critical area of focus for the industry.

Liquid cooling and air cooling are two primary methods used to manage the heat generated by servers in data centers. Here are the pros and cons of each approach:

### Air Cooling

### Pros

1. Ease of Implementation: Air cooling is the traditional method used in most data centers and is relatively straightforward to implement and maintain.
2. Lower Initial Cost: Air cooling infrastructure typically requires fewer upfront investments compared to liquid cooling systems.
3. Familiarity: Data center staff are generally more familiar with air cooling systems, which can simplify troubleshooting and maintenance.

### Cons

1. Limited Efficiency: Air cooling becomes less efficient as heat densities increase, especially with high-performance computing and dense server configurations.
2. Space Requirements: Air cooling may require more physical space for airflow management and large air handlers, limiting data center layout flexibility.
3. Energy Inefficiency: Cooling air requires significant energy consumption, contributing to higher operational costs and environmental impact.

### Liquid Cooling

### Pros

1. Higher Efficiency: Liquid cooling systems can be significantly more efficient than air cooling, especially for high-density computing environments. They can handle higher heat densities more effectively.
2. Space Savings: Liquid cooling can reduce the overall footprint required for cooling equipment compared to air-based solutions.
3. Improved Performance: By maintaining lower operating temperatures, liquid cooling can potentially extend the lifespan and improve the performance of server hardware.

### Cons

1. Complexity: Liquid cooling systems are more complex to design, install, and maintain compared to air cooling. They require expertise in fluid dynamics and thermal management.
2. Higher Initial Cost: Liquid cooling systems typically involve higher upfront costs due to specialized equipment such as pumps, pipes, and heat exchangers.
3. Potential for Leaks: The use of liquid introduces the risk of leaks, which could potentially damage server equipment and require careful monitoring and maintenance.

Choosing between air cooling and liquid cooling for data centers depends on factors such as heat density, scalability, initial investment budget, and operational efficiency goals. While air cooling is simpler and more cost-effective upfront, liquid cooling offers superior efficiency and space savings, especially for high-performance computing environments.

Another disadvantage of prior art cooling systems is the need for an extra hydronic system, which results in limited cooling power density, and reliability concerns because the chiller is concentrated.

Currently most prior art server cooling systems are liquid based systems referred to as CRAC(DX) or CRAH (CW). Both systems contain one liquid loop circulating liquid to outside chiller, another liquid loop circulating liquid to servers, and a heat exchanger exchanging heat between the liquids from the two loops. There is another variant design, named CRAC DX which is a type of Computer Room Air Conditioner (CRAC) that uses direct expansion (DX) refrigerant circulating between the server the above said heat exchanger. Such systems are comprised of filters, fans, coils and an external condenser, and are connected to a refrigerant pipework.

The systems are used as in-row and in-rack arrangements to increase efficiency. In addition, rear door liquid cooling is also used to reduce the waste of air cooling. Direct contact cooling (on-board cooling and immersion cooling) can be more efficient but has limitations (dependent on server structure, cold plate cannot cool all components, submerged server must be disassembled and separated from the pipe and liquid.

In the current implementation of CRAC/In-ROW/Rare door DX Liquid Cooling systems, DX refrigerant is used in direct contact. The current market products place the compressor at the outdoor which is away from the server, causing a large temperature difference between chiller suction and server temperature. In addition, the distance will increase the amount of refrigerant charging, increasing full life cycle impact on the environment.

At present, the DX system used in the data center market mainly adopts scroll type compressors. This type of compressor, in addition to CRAC unit integrated installation with compressor and evaporator nearby requires meaningful separation from other In-Row/Rear door equipment (usually 2 meters or several meters away) due to the size, weight, noise, vibration, oil maintenance, and the like. This results in a great loss of suction pressure, that is, suction saturation temperature, which increases the compressor energy consumption at the same evaporation temperature; In addition, the oil in the system has a hard time to return to the compressor from the cold plate which imposes reliability issues to the system.

Rear door liquid cooling is an integrated cooling mode. The operation of the Rear door liquid cooling integrated cabinet is affected by the size, weight, noise, vibration, and oil maintenance of the compressor, in that the space between the heat exchanger and the device is limited.

Although there are oil-free centrifugal compressors in the market that directly supply refrigerant to in-ROW/Rear door systems to complete DX mode systems, due to the large capacity of oil-free centrifugal compressors in the market at present, it has to operate with dozens of Rear door liquid cooling installations. Therefore, the installation position of the compressor is far away from the heat exchanger, resulting in a loss of suction pressure. One compressor failure will lead to multiple (e.g. dozens) of heat exchangers to lose cooling, leading to large losses.

Another disadvantage of current cooling systems is a lack of independence from energy rates. Prior art systems run constantly, regardless of the cost of energy, increasing operational costs.

### SUMMARY

The present system provides an improved architecture for cooling server cabinets as well as adapting operations based on dynamic energy costs. The system utilizes a small oil-free compressor, e.g. centrifugal type, which is distributed on the top of the cabinet, reducing the distance from the evaporator outlet to the compressor suction port, and combines phase change energy storage material and free cooling control technology to achieve further energy-saving effects. The technical scheme adopted by the invention to solve the technical problem is an oil-free direct-expansion cooled communication cabinet, characterized in that it is comprised of an oil-free compressor, with at least one condenser and one evaporator, a throttling device, a gas-liquid separation device, and a communication cabinet. The system stores cold capacity when energy costs are low and releases stored cold capacity when energy costs are high. The present system has an integrated design comprising a vapor compression refrigerant loop, an in rack cold plate loop, an in rack cold air loop, and a compressor motor and motor controller cooling loop.

### BRIEF DESCRIPTION OF THE DRAWINGS

FIG. 1 illustrates a backplane evaporator oil-free direct expansion air cooling cabinet in an embodiment of the system.

FIG. 2 illustrates a cold plate type oil-free direct expansion liquid or two-phase flow cooled cabinet in an embodiment of the system.

FIG. 3 illustrates a schematic of an embodiment of the oil-free system where multiple evaporators and condensers are integrated in the system.

FIG. 4 illustrates a schematic of an embodiment of the oil-free system with multiple evaporators and condensers, thermal energy storage unit, Fee cooling mode switch, and hot gas bypass.

FIG. 5 is a flow diagram illustrating the operation of the system in an embodiment.

FIG. 6 illustrates a functional block diagram of the system in an embodiment.

### DETAILED DESCRIPTION OF THE SYSTEM

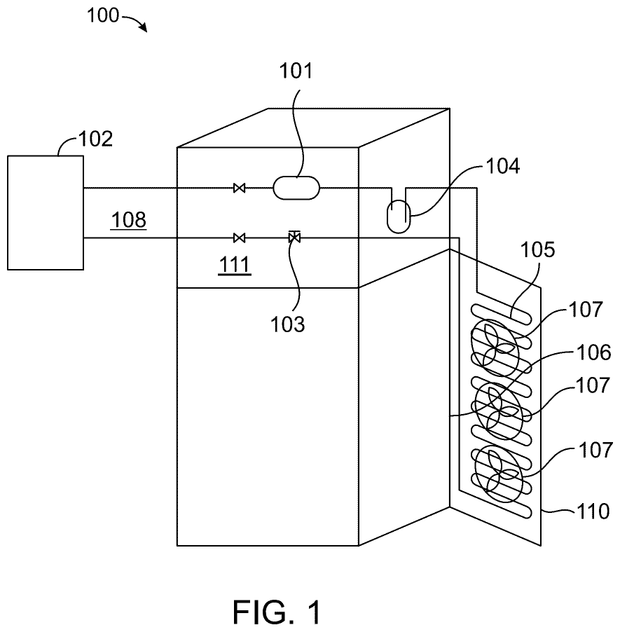

FIG. 1 illustrates a cabinet incorporating an embodiment of the system. The present embodiment 100 provides an oil-free direct expansion cooling communication cabinet 106. The cabinet 106 comprises an oil-free compressor 101, a condenser 102, a throttling device 103, a gas-liquid separation device 104, and an evaporator 105.

The oil-free compressor 101 and the gas-liquid separator 104 are placed on the top of cabinet 106 in an embodiment, which is gravitically higher than the evaporator 105. It is preferred to put compressor on the highest point of the rack. The condenser 102 is separated from the communication cabinet 106, placed remotely or outside the data center building, and connected through a joint and a pipeline 108. The throttling device 103 is connected with the evaporator 105 through a pipeline.

The evaporator 105 is placed on the backplane or door of the cabinet. The backplane is installed with air moving devices 107, e.g. fans, to achieve air circulation on the evaporator 105 and inside cabinet 106. The evaporator 105 is placed on the cabinet door 110 of the cabinet 106. The cabinet door 110 can be opened for maintenance operations. The connection pipe 111 between the evaporator 105 and the throttling device 103 and the gas-liquid separator 104 may be a flexible hose in an embodiment of the system.

The location of the evaporator 105 on the cabinet itself reduces the distance from the evaporator outlet to the compressor suction port. In an embodiment, the system combines phase change energy storage material and free cooling control technology to achieve further energy-saving effects.

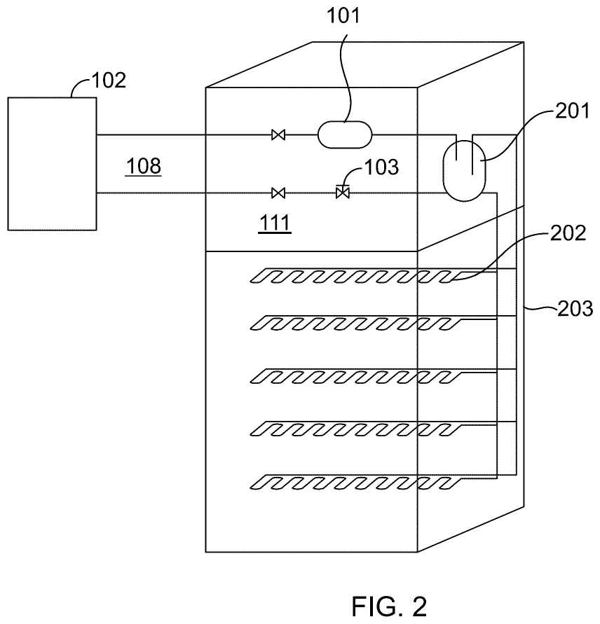

FIG. 2 illustrates a cold plate type DX cooled cabinet in an embodiment of the system. The present embodiment provides an oil-free direct expansion cooling communication cabinet 203, comprising an oil-free compressor 101, a condenser 102, a throttling device 103, a low pressure circulation barrel 201, and multiple cold plates 202.

The oil-free compressor 101 and the low-pressure circulation barrel 201 are placed near the top of the cabinet, and the condenser 102 is separated from the communication cabinet 203, placed remotely or outdoors (or at least outside the server room), and connected through a joint and a pipeline 108. The throttling device 103 is connected with the middle of the low pressure circulation barrel 201 through a pipeline 111. The compressor 101 is connected with the upper part of the low pressure circulation barrel 201. The outlet collecting tube of the evaporator 202 is connected with the middle and upper part of the low pressure circulation barrel 201, and the inlet collecting tube of the evaporator 202 is connected with the bottom of the low pressure circulation barrel 201. A plurality of evaporators 202 are placed on the server as cold plates and heat transfer in contact with the server heat source.

In the embodiment of FIG. 2, aerodynamic devices are not required due to the use of cooling plates. This can aid in reducing operating costs of the system.

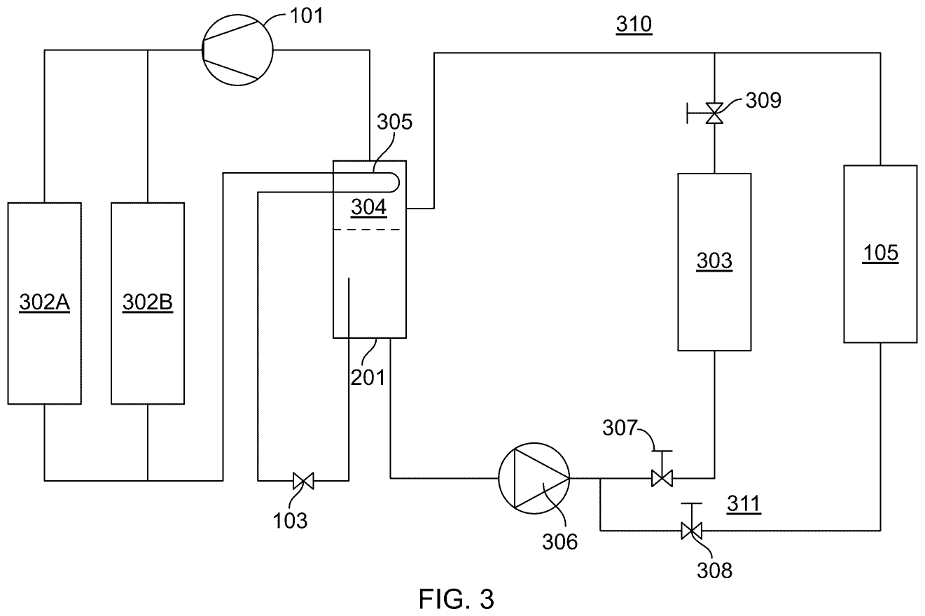

FIG. 3 illustrates a schematic of an embodiment of the system. The present embodiment provides an oil-free direct expansion cooling communication cabinet refrigeration system comprising an oil-free compressor 101, one or more condensers, e.g. 302A and 302B in one embodiment, a throttling device 103, a low pressure circulation barrel 201, an evaporator 105, a phase-change energy storage unit 303, and a heat recovery heat exchanger 304 inside the low pressure circulation barrel 201.

The heat recovery heat exchanger 304 in an embodiment is an inter-wall heat exchanger, which is composed of a curved tube 305. Liquid refrigerant flows out of condensers 302A and 302B, enters curved tube 305, and flow to the throttling device 103. The refrigerant gas separated from the low-pressure circulation barrel 201 is transferred outside the pipe for heat exchange. The liquid in the low-pressure circulation barrel 201 flows out from the bottom and is pressurized by a refrigerant pump 306.

The pressurized liquid is then divided into one or more paths, one of which is installed on the front valve 307 of the phase-change refrigerator, and then connected to the inlet of the phase-change refrigerator 303. The exit of phase change freezer 303 is connected to the exit valve 309 of phase change freezer through the pipeline, and then connected to the middle and upper part of the low pressure circulation barrel 201 through the pipeline 310.

The evaporator front valve 308 is installed on the other path, and is connected to the entrance of the evaporator 105 through the pipeline 311. The exit of the evaporator 105 is connected to the middle and upper part of the low pressure circulation barrel 201 through the pipeline 310. In this embodiment, the evaporator outlet 105 and the valve outlet 309 after the phase change freezer are first assembled and then connected to the low pressure circulation barrel 201. For instances when 303 and 105 require accurate pressure, either the same or different, a back pressure control valve can be added at the downstream of 105 before 310. The system can also expand with multiple evaporators in parallel with 105 and 303 with control valves at up and down stream locations.

When the design operating temperatures have high difference between heat exchanger 304 and evaporator 105, a bypass line can be added in parallel with refrigerant pump 306 with an active controlled flow valve. The refrigerant will self-circulate between heat exchanger 304 and 105 without the need to operate refrigerant pump 306.

This embodiment allows operation to be optimized to reduce electrical costs. Electricity costs are cheaper at certain times of day, depending on overall system load. The embodiment of FIG. 3 allows the system to both cool the cabinet and store cold capacity when electricity is lower cost.

When the electricity price is low, the system opens the valve 307 in front of the phase change refrigerator 303 and the valve 309 after the phase change refrigerator 303, and stores the excess cold capacity in the interior of the phase change refrigerator 303. When the electricity price is high, the cold capacity inside the phase change refrigerator 303 is released to reduce the cost of refrigeration. The phase-change freezer 303 can be placed on the top or by the side of the cabinet. The compressor 101 can run at low power consumption state or turned off. The cooling is realized through the siphon heat pipe effect. In addition, when there is a system power outage or compressor failure, the thermal storage unit 303 acts as an auxiliary unit which keeps the servers cool during emergency until system shut servers down safely.

In an embodiment, the phase change refrigerator 303 uses a phase change material (PCM) such as a eutectic material. The PCM can be a variety of materials based on phase change temperature, e.g. water, salt hydrate, and paraffin etc. During off peak electric rate periods, the system will be used to both cool the cabinets and to convert the PCM from a liquid phase to a solid phase. During peak electric rate periods, the PCM is allowed to transition from solid phase to liquid phase, and provide cooling to the server.

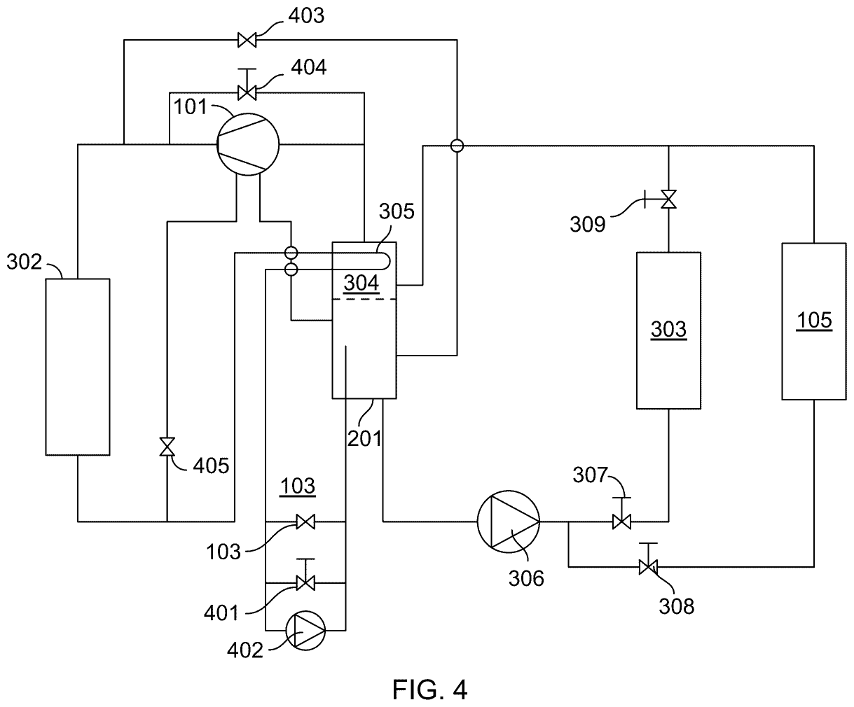

FIG. 4 illustrates a schematic of an embodiment of the system with PCM, Fee cooling capability, and hot gas bypass. The present embodiment provides an oil-free direct expansion cooling communication cabinet refrigeration system diagram comprising an oil-free compressor 101, one or more condensers e.g. 302., a throttling device 103, a low pressure circulation barrel 201, an evaporator 105 (can be multiple), and a heat recovery heat exchanger 305.

The heat recovery heat exchanger 305 is an inter-wall heat exchanger in an embodiment, which is composed of a curved tube 304 through which refrigerant liquid is returned from condenser 302. The refrigerant gas separated from the low-pressure circulation barrel 201 is transferred outside the pipe for heat exchange. The liquid refrigerant in the low-pressure circulation barrel 201 flows out from the bottom and is pressurized by a refrigerant pump 306. The operating mode between low pressure barrel 201, PCM module 303, and evaporator 105 is the same as in FIG. 3 system.

The embodiment provides a compressor 101 motor cooling circuit. The refrigerant cooled by condenser 102 cools the compressor 101 motor through the compressor motor cooling throttle valve 405 through the connecting pipeline. The refrigerant after heat absorption is connected to the middle and lower part of the low pressure circulation barrel 201 through the pipeline.

In this embodiment, the free cooling valve 403 is connected in parallel on the compressor 101 connection pipe. The free cooling valve 401 and the free cooling auxiliary refrigerant pump 402 are connected in parallel on the throttling device 103 connection pipe. When the temperature of condenser 302 is low, simply opening the free cooling valve 403 and the free cooling valve 401, and stop the operation of compressor 101 can meet the cooling requirements; When the temperature of condenser 302 is further increased and the gravity action of condenser 302 is not enough to realize the free cooling cycle, closing the free cooling valve 401 and opening the free cooling auxiliary refrigerant pump 402 can realize the free cooling cycle by not running compressor 101. A check valve can be added at the compressor discharge end to prevent compressor shaft from reverse spinning in free cooling mode.

In this embodiment, a hot gas by-pass regulating valve 404 is installed between the outlet line of oil-free compressor 101 and the low pressure circulation barrel 201. In order to avoid frequent opening and stopping of oil-free compressor 101 when the cooling load is low, the unloading function is realized by opening the hot gas by-pass regulating valve 404. The system can have multiple condensers in parallel with 302. And multiple evaporators in parallel with 105.

It should be understood that the above is only the preferred embodiment of the invention, and the scheme presented in the paper is only an example that is easy for technical personnel to understand. For ordinary technical personnel in the technical field, several improvements and refinements can be made without leaving the principle of the invention, and these improvements and refinements should also be considered as the scope of protection of the invention.

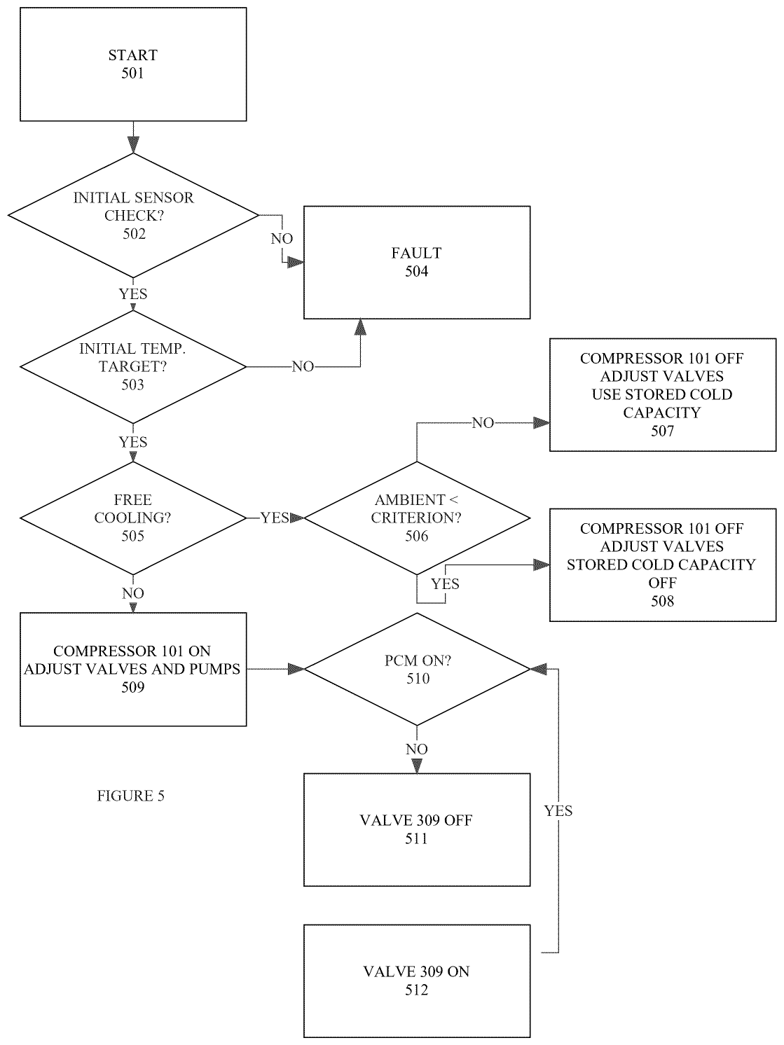

FIG. 5 is a flow diagram illustrating the operation of the system in the FIG. 4 embodiment. The system starts at step 501. At decision block 502, the system does an initial sensor check. If the sensor check passes, the system proceeds to decision block 503 to check the initial temperature target. If the checks fail at steps 502 or 503, the system triggers a fault at step 504. The fault can be reset either automatically or manually.

At decision block 505 it is determined if the current ambient temperature allows free cooling (e.g. from the stored cold capacity). If so, the system proceeds to decision block 506. Here it is determined whether the ambient temperature is less than the criterion (desired cabinet temperature). If not, the system proceeds to step 507 and opens valves 308 and 404. The Compressor 101 is shut down and valves 103, 405, and 401 are closed. Refrigerant pump 402 and 306 are turned on. (Free cooling means the heat from server transfer to ambient without a compressor. The system does not necessarily need a PCM module).

If the ambient temperature at step 506 is below the criterion temperature, the system proceeds to step 508. At step 508 the system opens valves 308, 404, and 401. Compressor 101 is shut down and valves 103 405, and 403 are closed. Refrigerant pump 402 and 406 are turned off, as no active cooling is required in this temperature condition.

If the current temperature does not allow free cooling at step 505, the system proceeds to step 509 to allow the cooling system to operate. The compressor 101 is turned on and valves 103, 308, 405 are opened. Refrigerant pump 402 is turned off. Refrigerant pump 306 is turned on. This provides cooling to the system.

At decision block 510 it is determined if the PCM 303 should be turned on or not. If no (when energy rates are above a threshold value) the system proceeds to step 411 and turns off valve 309. If yes, meaning energy rates are below the threshold) the system proceeds to step 512 and turns valve 309 on, so that excess cold capacity can be stored at PCM 303.

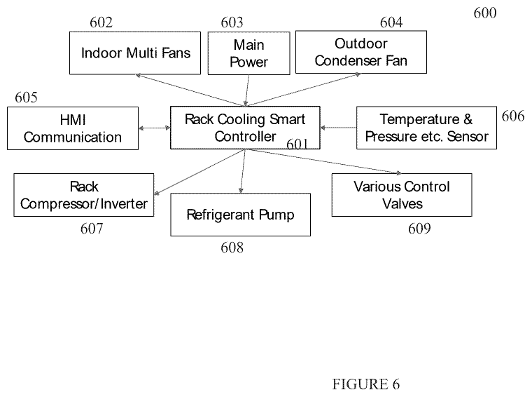

FIG. 6 illustrates a functional block diagram of the system in an embodiment. The system 600 implements a Rack Cooling Smart Controller 601. The Controller 601 includes the control programming for operating the cooling system. The Controller can be programmed and monitored via the HMI connection 605. This allows an operator to set the temperature targets, electricity rate values for engaging the PCM for storage or use, and other parameters. The HMI connection 605 can also provide electricity rate information dynamically if needed. In some embodiments, the electricity rate may be time based (cheaper in the middle of the night, more expensive during the day). The Controller is in communication with temperature and pressure sensors 606 that provide feedback about conditions in the cabinets so that appropriate cooling actions may be taken.

The system draws power from main power 603. The Controller 601 controls multiple indoor fans 602, and outdoor condenser fans 604. Finally, the Controller 601 interacts with and controls Rack Compressor/Inverter 607, refrigerant pump 608 and various control valves 609.

Thus, a method and apparatus for a cooling system has been described.

What is claimed is:

1. A cooling system for a communication cabinet comprising:
at least one oil free compressor;
at least one condenser;
at least one evaporator;
at least one throttling device coupled to the at least one evaporator;
a gas-liquid separation device;
at least one in-rack cold plate loop;
an in-rack cold air loop;
a liquid bypass circuit from an outlet of the at least one condenser that is expanded and cools the at least one oil free compressor components with a liquid refrigerant, and returns to the gas-liquid separation device.

2. The system of claim 1 wherein the at least one condenser is separated from the communication cabinet.

3. The system of claim 1 wherein the gas-liquid separator is gravitically higher than the at least one evaporator where:
liquid refrigerant, supplied by the at least one condenser, flows through the at least one throttling device, and then is connected with the middle of the gas-liquid separation device;
the at least one oil free compressor is connected with the upper part of the gas-liquid separation device;
an outlet collecting tube of the at least one evaporator is connected with a middle and upper part of the gas-liquid separation device and an inlet collecting tube of the at least one evaporator is connected with a bottom of the gas-liquid separation device.

4. The cooling system of claim 3, further comprising a refrigerant pump configured to pressurize liquid refrigerant flowing from the bottom part of the gas-liquid separation device and discharge high pressure liquid into the at least one evaporator.

5. The cooling system of claim 4, further comprising either a flow or pressure control valve at upstream and downstream of the at least one evaporator.

6. The cooling system of claim 5 further including a heat exchanger inside the gas-liquid separation device wherein the heat exchanger inlet and outlet connect to the at least one condenser.

7. The refrigeration unit of claim 1 further comprising:
a. a thermal energy storage system comprising a container; at least one heat exchange apparatus disposed within the container, a phase change material disposed within the tank and in apparatus;
b. wherein the at least one heat exchange apparatus exchanges heat between system refrigerant and the phase change material; and
c. wherein the thermal energy storage system is located in parallel with the at least one evaporator via flow control valves.

8. The system of claim 4 wherein:
a. a free cooling valve is connected in parallel with the at least one oil free compressor
b. a free cooling valve and a free cooling auxiliary refrigerant pump are connected in parallel with the at least one throttling device.

9. The system of claim 8 wherein a bypass loop with a flow control valve is connected in parallel with the at least one oil free compressor.
